(19) United States
(12) Patent Application Publication
(10) Pub. No.: US 2023/0407173 A1
(43) Pub. Date: Dec. 21, 2023

(54) PHOSPHOR AND SOLAR CELL MODULE USING SAME

(71) Applicant: Panasonic Intellectual Property Management Co., Ltd., Osaka (JP)

(72) Inventors: RIHO MORIYAMA, Osaka (JP); KEI TOYOTA, Osaka (JP)

(21) Appl. No.: 18/460,734

(22) Filed: Sep. 5, 2023

Related U.S. Application Data
(63) Continuation of application No. PCT/JP2022/008122, filed on Feb. 28, 2022.

(30) Foreign Application Priority Data
Mar. 15, 2021 (JP) 2021-041245

(51) Int. Cl. C09K 11/77; C01B 33/26; H01L 31/048; H01L 31/055

(52) U.S. Cl. CPC C09K 11/77344; C01B 33/26; H01L 31/0481; H01L 31/055; C01P 2002/52; C01P 2004/61

(57) ABSTRACT

A phosphor includes silica particles as a base material, Eu, Al, and an alkaline earth metal that is Ca or Mg. The phosphor contains 0.01 mol to 15 mol of the Eu in terms of metal element with respect to 100 mol of the silica particles, 0.5 mol to 25 mol of the Al in terms of metal element with respect to 100 mol of the silica particles, and 0.1 mol to 2.0 mol of the alkaline earth metal in terms of metal element with respect to 100 mol of the silica particles.

### TECHNICAL FIELD

The present disclosure relates to a phosphor and a solar cell module using the phosphor.

### BACKGROUND ART

Solar cell modules typically have low sensitivity characteristics in a short wavelength region and cannot effectively use light in a short wavelength region such as ultraviolet rays contained in sunlight. Efforts have been heretofore made to improve the efficiency of solar cell modules by using, as a wavelength conversion material, a phosphor that absorbs light in a short wavelength region and emits fluorescence in a long wavelength region such as visible light to increase the amount of light in the long wavelength region in which a photoelectric conversion device has high sensitivity characteristics.

On the other hand, a photoelectric conversion device of a solar cell module is deteriorated by being irradiated with light in a high-energy ultraviolet region (hereinafter, referred to as “ultraviolet ray”) having a wavelength of less than or equal to 350 nm for a long time. For this reason, it is desirable that ultraviolet rays are removed as much as possible from light reaching the photoelectric conversion device, and an ultraviolet absorber is commonly blended in a filler on a front surface of the photoelectric conversion device. If ultraviolet rays can be sufficiently absorbed only by a phosphor, it is not necessary to use an ultraviolet absorber, but in many cases, ultraviolet rays cannot be sufficiently absorbed only by a phosphor, and in such a case, it is necessary to use a phosphor and an ultraviolet absorber in combination.

Thus, for example, in PTL 1, with a structure in which a phosphor sheet material made of a transparent resin containing a phosphor is disposed on an upper side of a filler layer containing an ultraviolet absorber, ultraviolet rays are firstly absorbed by the phosphor sheet material layer on the upper side containing the phosphor, fluorescence is emitted, and then ultraviolet rays that could not be absorbed are absorbed by the filler layer on the lower side. With this configuration, it is tried to achieve both high efficiency by the phosphor and ultraviolet absorption by the ultraviolet absorber.

### CITATION LIST

### Patent Literature

PTL 1: Unexamined Japanese Patent Publication No. 2018-182074

### SUMMARY OF THE INVENTION

A phosphor according an aspect of the present disclosure includes silica particles as a base material, Eu, Al and an alkaline earth metal that is Ca or Mg. The phosphor contains 0.01 mol to 15 mol of the Eu in terms of metal element with respect to 100 mol of the silica particles, 0.5 mol to 25 mol of the Al in terms of metal element with respect to 100 mol of the silica particles, and 0.1 mol to 2.0 mol of an alkaline earth metal in terms of metal element with respect to 100 mol of the silica particles.

### BRIEF DESCRIPTION OF THE DRAWINGS

FIG. 1 is a diagram showing an emission spectrum of a phosphor according to a first exemplary embodiment when the phosphor is irradiated with an excitation light source of 365 nm.

FIG. 2 is a schematic sectional view showing a sectional structure of solar cell module 10 according to the first exemplary embodiment.

FIG. 3A is a schematic sectional view showing a sectional structure in a state where a phosphor is uniformly attached to an ultraviolet absorber-containing resin in a method for manufacturing solar cell module 10 according to the first exemplary embodiment.

FIG. 3B is a schematic sectional view showing a sectional structure in a state where the phosphor is embedded in the ultraviolet absorber-containing resin in the method for manufacturing solar cell module 10 according to the first exemplary embodiment.

FIG. 4 is Table 1 showing the relative output and evaluation of the phosphors according to Examples 1 to 12 and solar cell modules using the phosphors.

FIG. 5 is Table 2 showing the relative output and evaluation of the phosphors according to Comparative Examples 1 to 9 and solar cell modules using the phosphors.

### DESCRIPTION OF EMBODIMENT

For the phosphor and a resin in which the phosphor is to be embedded, materials having similar refractive indexes are used to ensure transparency. However, since the refractive indexes do not completely match each other, the transparency of the resin decreases because of the influence of embedding the phosphor in the resin, and the amount of sunlight reaching the photoelectric conversion devices decreases, and thus, the conversion efficiency of the solar cell module decreases. Thus, to improve the conversion efficiency of the solar cell module, a phosphor having light emission exceeding the light amount decrease of sunlight reaching the photoelectric conversion device, the decrease being caused by the decrease in transparency of the resin because of the influence of embedding the phosphor in the resin, is required, but the light emission of the phosphor used in PTL 1 is not sufficient.

The present disclosure solves the above-described conventional problem, and an object of the present disclosure is to provide a phosphor capable of increasing the amount of visible light that reaches a photoelectric conversion device when the phosphor is used in a solar cell module.

A phosphor according a first aspect includes silica particles as a base material, Eu, Al and an alkaline earth metal that is Ca or Mg. The phosphor contains 0.01 mol to 15 mol of the Eu in terms of metal element with respect to 100 mol of the silica particles, 0.5 mol to 25 mol of the Al in terms of metal element with respect to 100 mol of the silica particles, and 0.1 mol to 2.0 mol of the alkaline earth metal in terms of metal element with respect to 100 mol of the silica particles.

A phosphor according a second aspect may include, 1.5 mol to 4.0 mol of the Eu in terms of metal element with respect to 100 mol of the silica particles, and 10 mol to 20 mol of the Al in terms of metal element with respect to 100 mol of the silica particles.

In a phosphor according to a third aspect, in the first or second aspect, the silica particles may have an average particle size of from 5 μm to 50 μm inclusive.

A solar cell module according to fourth aspect includes a backsheet, a protective glass, a first filler layer disposed between the backsheet and the protective glass, a second filler layer disposed between the protective glass and the first filler layer, an electrode disposed between the first filler layer and the second filler layer, and a photoelectric conversion device disposed between the first filler layer and the second filler layer and connected to the electrode, wherein the second filler layer contains an ultraviolet absorber-containing resin and the phosphor according to any one of first to third aspects.

Hereinafter, a phosphor and a solar cell module according to an exemplary embodiment will be described in detail with reference to the drawings.

### First Exemplary Embodiment

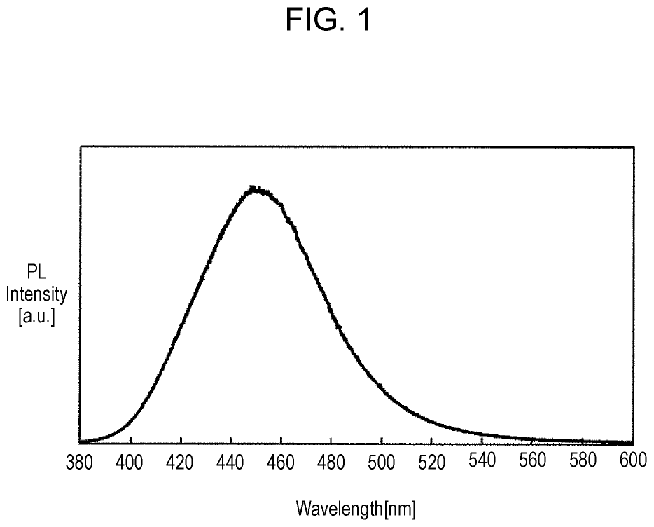

FIG. 1 is a diagram showing an emission spectrum of a phosphor according to a first exemplary embodiment when the phosphor is irradiated with an excitation light source of 365 nm. The phosphor includes silica particles as a base material, and in terms of metal element with respect to 100 mol of the silica particles, 0.01 mol to 15 mol of Eu, 0.5 mol to 25 mol of Al, and 0.1 mol to 2.0 mol of an alkaline earth metal. The alkaline earth metal is Ca or Mg. When the phosphor is irradiated with light in an ultraviolet region of 356 nm, blue light emission having a peak in the vicinity of 450 nm is exhibited.

The phosphor according to the first exemplary embodiment, including silica particles as the matrix and thus having a small refractive index difference with resin used for a solar cell module, can secure the transparency of the resin. Thus, the amount of visible light to be transmitted to a photoelectric conversion device increases even when the phosphor is used for a solar cell module, and a highly efficient solar cell module can be provided.

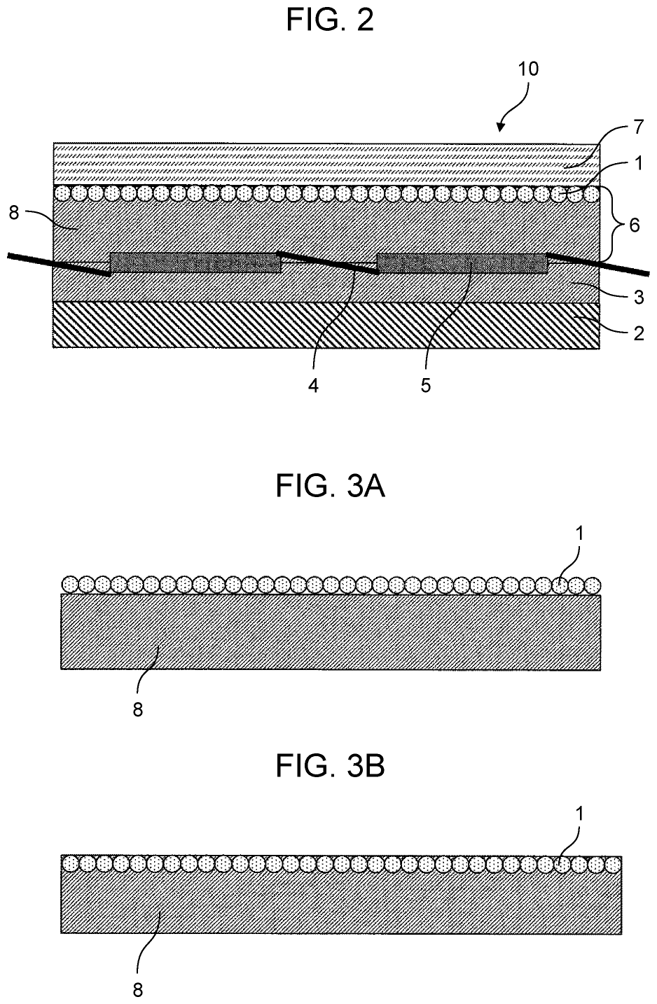

FIG. 2 is a schematic sectional view showing a sectional structure of solar cell module 10 according to the first exemplary embodiment. FIG. 2 is an example of a solar cell module structure.

Solar cell module 10 has a structure in which backsheet 2, first filler layer 3, photoelectric conversion device 5, second filler layer 6, and protective glass 7 are stacked in this order in solar cell module 10. First filler layer 3 protects a back surface of photoelectric conversion device 5. Photoelectric conversion device 5 is electrically connected to electrode 4. Second filler layer 6 includes phosphor 1 and ultraviolet absorber-containing resin 8, and phosphor 1 has a structure disposed at an upper end of second filler layer 6. In other words, first filler layer 3 is disposed between backsheet 2 and protective glass 7. Second filler layer 6 is disposed between protective glass 7 and first filler layer 3. Electrode 4 is disposed between first filler layer 3 and second filler layer 6. Photoelectric conversion device 5 is disposed between first filler layer 3 and second filler layer 6.

A process from when sunlight enters into solar cell module 10 until when the sunlight reaches the photoelectric conversion device 5 will be described using solar cell module 10 of FIG. 2 as an example.

a) Sunlight first passes through protective glass 7 and reaches second filler layer 6.

b) The sunlight hits phosphor 1 disposed at the upper end of second filler layer 6, and ultraviolet rays are converted into visible light. Ultraviolet rays that has not been converted is absorbed by an ultraviolet absorber contained in ultraviolet absorber-containing resin 8 constituting second filler layer 6, and the visible light passes through second filler layer 6 and reaches photoelectric conversion device 5.

In phosphor 1 according to the first exemplary embodiment, sunlight hits phosphor 1, and the amount of ultraviolet rays that can be converted into visible light is large. Thus, a larger amount of visible light in which photoelectric conversion device 5 has high sensitivity characteristics can be delivered.

<Phosphor>

Phosphor 1 is a wavelength conversion material that absorbs light in a short wavelength region and emits fluorescence in a long wavelength region. Phosphor 1 includes silica particles as a base material and, as luminescence centers, Eu, Al, and an alkaline earth metal, and the alkaline earth metal is Ca or Mg.

The content of Eu is 0.01 mol to 15 mol in terms of metal element with respect to 100 mol of the silica particles. When the amount of Eu is too large, the light emission intensity is saturated, but the light emission intensity may decrease because of concentration quenching caused by an increase in the concentration of Eu. The content is more preferably 1.5 mol to 4.0 mol. This configuration can more sufficiently exhibit the light emission intensity.

The content of Al is 0.5 mol to 25 mol in terms of metal element with respect to 100 mol of the silica particles. When the amount of Al is too large, the light emission intensity is saturated, but the light emission intensity may decrease because of a change in the crystal structure of the phosphor base material. When the amount of Al is too small, the crystal structure around the luminescence center cannot be affected, and sufficient light emission intensity cannot be exhibited. The content is more preferably 10 mol to 20 mol. This configuration can more sufficiently exhibit the light emission intensity.

The content of the alkaline earth metal is 0.1 mol to 2.0 mol in terms of metal element with respect to 100 mol of the silica particles. When the amount of the alkaline earth metal is too large, the light emission intensity decreases because of a change in the crystal structure of the phosphor matrix.

Since the main component of the silica particles is silica, that is, silicon dioxide, the refractive index thereof is larger than 1.49 and smaller than 1.51. Thus, when the filler resin serving as the matrix of ultraviolet absorber-containing resin 8 is an ethylene-vinyl acetate copolymer or polyethylene, the silica particles have a refractive index close to those of the ethylene-vinyl acetate copolymer or polyethylene, and thus transparency can be improved.

The average particle size of the silica particles of phosphor 1 is preferably from 5 μm to 50 μm inclusive. When the average particle size is smaller than 5 μm, the particles are easily aggregated, and when the particles are aggregated, air is entrapped between the particles, and light is scattered at the interface. When the average particle size is larger than 50 μm, scattering of light with the particles increases. As the scattering of light increases, the transparency of second filler layer 6 is impaired, which disturbs improvement in efficiency. In the present exemplary embodiment, the average particle size of the silica particles of phosphor 1 is calculated from a number-based particle size distribution, and is defined as a value of median diameter D50. Phosphor 1 is preferably spherical particles from the viewpoint of uniform dispersion.

Phosphor 1 preferably absorbs ultraviolet light of less than or equal to 400 nm and emits fluorescence having a wavelength longer than 400 nm from the viewpoint of improving efficiency by absorbing light in a short wavelength region in which photoelectric conversion device 5 has low sensitivity characteristics and emitting light as fluorescence in a long wavelength region in which photoelectric conversion device 5 has high sensitivity characteristics.

<Backsheet>

Backsheet 2 is a protective member for preventing water and foreign substances from entering the inside from the back surface of solar cell module 10, and for example, a polyethylene terephthalate film or the like may be used.

<Ultraviolet Absorber-Containing Resin>

Ultraviolet absorber-containing resin 8 is made of a transparent resin containing an ultraviolet absorber.

<Transparent Resin>

As the transparent resin, polyvinyl chloride, polyvinylidene chloride, polyvinyl alcohol, a polystyrene styrene-acrylonitrile copolymer, a styrene-butadiene-acrylonitrile copolymer, polyethylene, an ethylene-vinyl acetate copolymer, polypropylene, polymethyl methacrylate, a methacryl-styrene polymer, cellulose acetate, polycarbonate, polyester, PET, vinylidene trifluoride, an epoxy resin, a silicon resin, polyether sulfone, cycloolefin, triacetate, and the like may be used singly, and two or more thereof may be mixed and used.

The thickness of the transparent resin is preferably from 100 μm to 1000 μm inclusive. When the thickness is less than 100 μm, ultraviolet rays that have not been absorbed by phosphor 1 cannot be sufficiently absorbed, and damage to photoelectric conversion device 5 from ultraviolet rays cannot be reduced. When the thickness is more than 1000 μm, absorption of light in the visible region by the transparent resin itself increases, causing a decrease in conversion efficiency of the photoelectric conversion device 5, which is not preferable.

<Ultraviolet Absorber>

The ultraviolet absorber contained in the transparent resin is not limited to any composition or system, but an ultraviolet absorber having a peak of an absorption wavelength of from 300 nm to 400 nm inclusive may be used. When the peak of the absorption wavelength is on the shorter wavelength side than the wavelength of 300 nm, the wavelength of ultraviolet rays that have not been absorbed by phosphor 1 cannot be sufficiently absorbed, and damage to photoelectric conversion device 5 from ultraviolet rays increases. When the peak of the absorption wavelength is on the longer wavelength side than the wavelength of 400 nm, the peak is outside the wavelength region of ultraviolet rays that have passed through phosphor 1, and thus, it becomes difficult to protect photoelectric conversion device 5 from ultraviolet rays. Further, light in a long wavelength region emitted from phosphor 1 is also absorbed, which disturbs improvement in output with conversion of phosphor 1. As the ultraviolet absorber, it is preferable to use an organic ultraviolet absorber represented by a triazine-based compound, a benzotriazole-based compound, a benzophenone-based compound, and the like from the viewpoint of high transparency. The ultraviolet absorber may be used singly or in combination of two or more thereof.

The addition amount of the ultraviolet absorber may be determined to achieve a transmittance of less than 5% at an absorption wavelength of 300 nm to 400 nm.

<Electrode>

Photoelectric conversion device 5 is electrically joined by electrode 4. As electrode 4, a known metal material or alloy metal may be used. Electrode 4 may include a pair of electrodes 4. An output from photoelectric conversion device 5 can be obtained by the pair of electrodes 4. In addition, in a case where a plurality of photoelectric conversion devices 5 are connected to each other, photoelectric conversion devices 5 are connected to the pair of electrodes 4 in such a manner that an output can be obtained in each case of series connection and parallel connection.

<Photoelectric Conversion Device>

As photoelectric conversion device 5, a silicon semiconductor such as a single-crystalline silicon-based semiconductor, a polycrystalline silicon-based semiconductor, or an amorphous silicon-based semiconductor, or a compound semiconductor such as gallium arsenide or cadmium telluride may be used. Photoelectric conversion device 5 may include a plurality of photoelectric conversion devices 5 electrically connected to each other. When a plurality of photoelectric conversion devices 5 are used, photoelectric conversion devices 5 may be connected in series or in parallel.

<Protective Glass>

As protective glass 7, a known plate-like glass having translucency and water shielding property may be used.

<First Filler Layer>

As first filler layer 3 on the back surface for protecting photoelectric conversion device 5, an ethylene-vinyl acetate copolymer, a bisphenol epoxy resin cured product, polyethylene, an acrylic resin, a silicon resin, a polycarbonate resin, or the like may be used singly. Two or more of these may also be mixed and used.

<Second Filler Layer>

Second filler layer 6 is a sheet in which a plurality of phosphors 1 are unevenly distributed in ultraviolet absorber-containing resin 8. A configuration in which phosphors 1 are unevenly distributed on protective glass 7 side of ultraviolet absorber-containing resin 8, that is, on the light incident surface side, is preferable.

(Method for producing phosphor)

A process for manufacturing phosphor 1 according to the first exemplary embodiment will be described.

(1) First, aqueous solutions individually containing Eu, Al, and an alkaline earth metal at a desired concentration are prepared, each aqueous solution is added to silica particles in a desired molar amount with respect to 100 mol of the silica particles, stirred in a beaker, mixed for about 1 minute, and left for 2 hours. Because of the porous structure of the silica particles, the aqueous solution penetrates into the inside because of the osmotic pressure, and each element penetrates into the inside from the periphery of the silica particles.

(2) Next, the silica particles into which each element has been penetrated are filtered using a vacuum filtration device, and the particles taken out are put in a drying furnace and dried at 120° C. to remove moisture. Thereafter, firing is performed at 1000° C. for 4 hours in a firing furnace in a reducing atmosphere. The firing temperature is less than or equal to 1100° C. The temperature is preferably more than or equal to 900° C., and more preferably more than or equal to 900° C.

Phosphor 1 having a wavelength conversion function of absorbing light in a short wavelength region and emitting fluorescence in a long wavelength region can be thus manufactured.

(Method for manufacturing solar cell module)

A manufacturing process of solar cell module 10 according to the first exemplary embodiment will be described.

(1) First, ultraviolet absorber-containing resin 8 is produced. An ultraviolet absorber is dissolved or decomposed in advance by a known method such as blending and kneading an ultraviolet absorber in a thermally dissolved transparent resin, to produce ultraviolet absorber-containing resin 8 formed into a sheet shape by roll stretching or hot pressing. For example, 1 g of a benzophenone-based ultraviolet absorber is added to 200 g of an ethylene-vinyl acetate copolymer, and they are mixed at 100 rpm for about 30 minutes in a planetary mixer heated to 120° C. Further, the mixture is subjected to gap adjustment with a stainless steel spacer having a constant thickness using a hot press machine heated to 120° C., and the mixture is pressed and cooled, whereby ultraviolet absorber-containing resin 8 is produced.

(2) Next, phosphor 1 in a particulate form and ultraviolet absorber-containing resin 8 are prepared, and second filler layer 6 in which phosphors 1 are unevenly distributed is manufactured. An appropriate amount of phosphors 1 are attached to ultraviolet absorber-containing resin 8 and uniformly distributed with, for example, an end of a spatula plate, a squeegee, a brush, or the like (FIG. 3A). At this time, phosphors 1 stably attach to ultraviolet absorber-containing resin 8 with electrostatic force, physical adsorption, or the like. Further, ultraviolet absorber-containing resin 8 of which phosphors 1 are uniformly attached and held on the surface is subjected to hot pressing while a constant gap is maintained with a spacer or the like. Phosphor 1 in a particulate form attached to the surface can be thus embedded in ultraviolet absorber-containing resin 8, and second filler layer 6 can be formed (FIG. 3B). From the viewpoint of embedding phosphor 1 in ultraviolet absorber-containing resin 8 while heating, this process is not limited to hot pressing, and a heat roll method or the like may also be used.

(3) Next, a step of laminating second filler layer 6 together with another member to obtain a solar cell module will be described. In this step, backsheet 2, first filler layer 3, photoelectric conversion device 5 electrically connected by electrode 4, second filler layer 6 produced as described above, and protective glass 7 are stacked in this order and subjected to a laminate treatment, whereby solar cell module 10 is produced.

Hereinafter, Examples and Comparative Examples will be specifically described.

### EXAMPLE 1

In Example 1, phosphor 1 containing silica particles as a base material, Eu, Al, and Ca as an alkaline earth metal was produced.

(1) First, europium nitrate containing Eu, aluminum nitrate containing Al, and calcium nitrate containing Ca were each dissolved in ion-exchanged water to prepare a 1 mol/L aqueous nitrate solution for each. To silica particles having an average particle size of 10 μm, the 1 mol/L europium nitrate aqueous solution, the 1 mol/L aluminum nitrate aqueous solution, and the 1 mol/L calcium nitrate aqueous solution were added in an amount of 2.0 mol, 15 mol, and 1.5 mol, respectively, with respect to 100 mol of silica. The mixture was stirred in a beaker, mixed for about 1 minute, and left to stand for 2 hours to allow Eu, Al, and Ca to penetrate into the inside of the silica particles.

(2) Thereafter, the silica particles into which Eu, Al and Ca have been penetrated were filtered using a vacuum filtration device, and the particles taken out were dried at 120° C. in a drying furnace to remove moisture.

(3) Thereafter, firing was performed at 1000° C. for 4 hours in a firing furnace in a reducing atmosphere to produce phosphor 1 containing 2.0 mol, 15 mol, and 1.5 mol of Eu, Al, and Ca, respectively, with respect to 100 mol of silica.

Next, a solar cell module for evaluation was produced using the phosphor prepared as above.

(a) As an ultraviolet absorber, 1 g of 2,4-dihydroxybenzophenone, which is a benzophenone-based ultraviolet absorber, was added to 200 g of low density polyethylene, they were mixed at 100 rpm for about 30 minutes in a planetary mixer heated to 150° C., and the mixture was subjected to gap adjustment with a 550 μm stainless steel spacer using a hot press machine heated to 150° C., pressed, and cooled, whereby ultraviolet absorber-containing resin 8 was obtained.

(b) Phosphor 1 was attached to ultraviolet absorber-containing resin 8 in an amount of 500 μg per 1 cm 2 and subjected to gap adjustment with a stainless spacer using a hot press machine heated to 150° C. to embed the plurality of phosphors 1 in a particulate form in the vicinity of the surface of ultraviolet absorber-containing resin 8. Second filler layer 6 was thus obtained.

(c) In addition, protective glass 7, second filler layer 6 in which the uneven distribution region of phosphor 1 was disposed on protective glass 7 side, photoelectric conversion devices 5 connected to each other by electrode 4, first filler layer 3, and backsheet 2 were stacked in this order and laminated to form a module for evaluation.

### EXAMPLES 2 To 4

Example 2 is the same as Example 1 except that the content of Ca in phosphor 1 is mol.

Example 3 is the same as Example 1 except that the content of Ca in phosphor 1 is 2.0 mol.

Example 4 is the same as Example 1 except that the alkaline earth metal is Mg.

Example 5 is the same as Example 4 except that the content of Mg in phosphor 1 is 0.1 mol.

Example 6 is the same as Example 4 except that the content of Mg in phosphor 1 is 2.0 mol.

Example 7 is the same as Example 1 except that the content of Eu in phosphor 1 is mol.

Example 8 is the same as Example 1 except that the content of Eu in phosphor 1 is mol.

Example 9 is the same as Example 1 except that the content of Al in phosphor 1 is mol.

Example 10 is the same as Example 1 except that the content of Al in phosphor 1 is 25 mol.

Example 11 is the same as Example 1 except that the average particle size of the silica particles of phosphor 1 is 5 μm.

Example 12 is the same as Example 1 except that the average particle size of the silica particles of phosphor 1 is 50 μm.

### COMPARATIVE EXAMPLES 2 To 4

Comparative Example 1 is the same as Example 1 except that no alkaline earth metal is contained.

Comparative Example 2 is the same as Example 1 except that the content of Ca in phosphor 1 is 0.05 mol.

Comparative Example 3 is the same as Example 1 except that the content of Ca in phosphor 1 is 2.2 mol.

Comparative Example 4 is the same as Example 4 except that the content of Mg in phosphor 1 is 0.05 mol.

Comparative Example 5 is the same as Example 4 except that the content of Mg in phosphor 1 is 2.2 mol.

Comparative Example 6 is the same as Example 1 except that the content of Eu in phosphor 1 is 0.008 mol.

Comparative Example 7 is the same as Example 1 except that content of Eu in phosphor 1 is 16 mol.

Comparative Example 8 is the same as Example 1 except that the content of Al in phosphor 1 is 0.45 mol.

Comparative Example 9 is the same as Example 1 except that the content of Al in phosphor 1 is 26 mol.

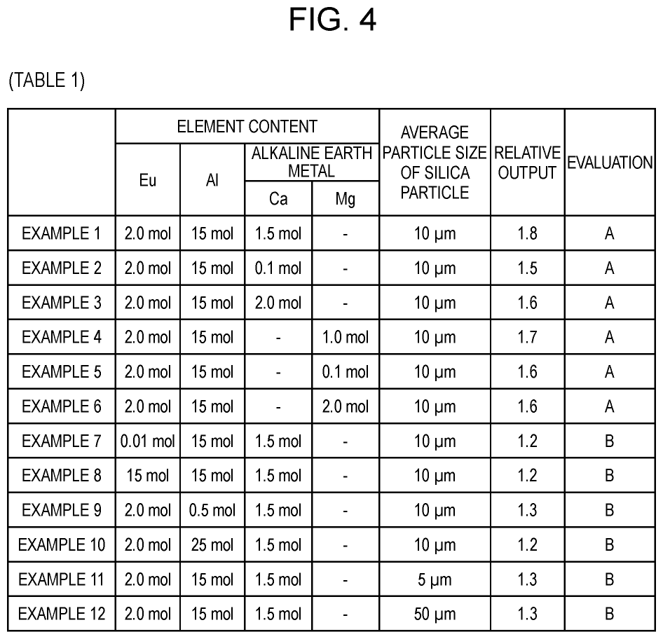

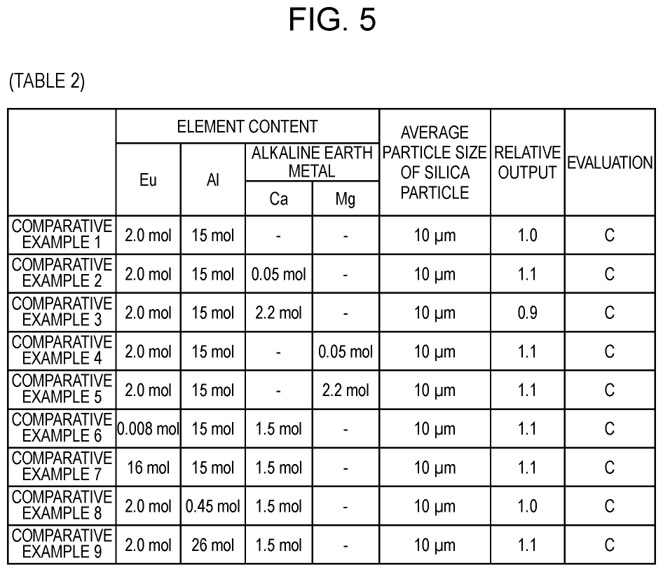

FIG. 4 is Table 1 showing the relative output and evaluation of the phosphors according to Examples 1 to 12 and solar cell modules using the phosphors. FIG. 5 is Table 2 showing the relative output and evaluation of the phosphors according to Comparative Examples 1 to 9 and solar cell modules using the phosphors.

(Output value)

For each of the produced modules for evaluating a solar cell module, the output at the time of irradiation with Xe lamp light with solar simulation was measured, and the relative output value with respect to the output value of Comparative Example 1 was obtained. The relative output value was calculated from the equation: relative output value=measured output value/output value of Comparative Example 1.

Determination criteria

### Evaluation

As a range with very excellent improvement in output value, more than or equal to 1.5 ••• A

As a range with excellent improvement in output value, more than or equal to 1.2 and less than 1.5 ••• B

As a range with poor improvement in output value, less than 1.2 ••• C

When the relative output value was more than or equal to 1.5, the solar cell module can be put into practical use as a commercial product, and the range was determined as very excellent in output value. When the relative output value was more than or equal to 1.2 and less than 1.5, light emission exceeding the light amount decrease of sunlight reaching the photoelectric conversion device, the decrease being caused by the decrease in transparency of the resin because of the influence of embedding the phosphor in the resin, was exhibited, and the range was determined as excellent in output value. The range of less than 1.2 was determined as poor in output value.

The following can be found from the results of Examples in Table 1 and Comparative Examples in Table 2.

Comparison of Examples 1, 2, 3, 4, 5, and 6 with Comparative Example 1 shows that the output value of solar cell module 10 improves when an alkaline earth metal is contained.

Comparison of Examples 1, 2, and 3 with Comparative Examples 2 and 3 shows that the output value of solar cell module 10 improves when 0.1 mol to 2.0 mol of Ca is contained as the alkaline earth metal.

Comparison of Examples 4, 5, and 6 with Comparative Examples 4 and 5 shows that the output value of solar cell module 10 improves when 0.1 mol to 2.0 mol of Mg is contained as the alkaline earth metal.

Comparison of Examples 1, 7, and 8 with Comparative Examples 6 and 7 shows that the output value of solar cell module 10 improves when 0.01 mol to 15 mol of Eu is contained, and further, comparison of Example 1 with Examples 7 and 8 shows that the output value of solar cell module 10 further improves when 1.5 mol to 4.0 mol of Eu is contained.

Comparison of Examples 1, 9, and 10 with Comparative Examples 8 and 9 shows that the output value of solar cell module 10 improves when 0.5 mol to 25 mol of Al is contained, and further, comparison of Example 1 with Examples 9 and 10 shows that the output value of solar cell module 10 further improves when 10 mol to 20 mol of Eu is contained.

From Examples 1, 11, and 12, it can be seen that the output value of solar cell module 10 improves when the average particle size of the silica particles is from 5 μm to 50 μm inclusive. When the average particle size of the silica particles is smaller than 5 μm, the particles are aggregated with each other, which causes a decrease in transparency and a decrease in output value when the silica particles are mixed with a resin. Further, when the average particle size is larger than 50 μm, irregular reflection occurs when the silica particles are mixed with a resin, which causes a decrease in transparency and a decrease in output value. Thus, the average particle size of the silica particles is preferably from 5 μm to 50 μm inclusive.

As described above, the phosphor according to an aspect of the present disclosure has very high light emission, with which a larger amount of visible light in which photoelectric conversion device has high sensitivity characteristics can be delivered. In addition, since the matrix of the phosphor is silica particles, a difference in refractive index with resin is small, and thus, transparency of the resin can be secured. Thus, the amount of visible light to be transmitted to the photoelectric conversion device increases, and a highly efficient solar cell module can be provided.

Note that the present disclosure includes an appropriate combination of any exemplary embodiment and/or example among the various above-described exemplary embodiments and/or examples, and effects of each of the exemplary embodiments and/or examples can be achieved.

### INDUSTRIAL APPLICABILITY

As described above, the phosphor according to an aspect of the present disclosure has very high light emission and a small difference in refractive index with resin, and thus is excellent as a wavelength conversion material of a solar cell module. Therefore, the phosphor has high industrial applicability.

### REFERENCE MARKS IN THE DRAWINGS

1 phosphor
2 backsheet
3 first filler layer
4 electrode
5 photoelectric conversion device
6 second filler layer
7 protective glass
8 ultraviolet absorber-containing resin
10 solar cell module

1. A phosphor comprising:
silica particles as a base material;
Eu;
Al; and
an alkaline earth metal that is Ca or Mg, wherein
the phosphor contains:
0.01 mol to 15 mol of the Eu in terms of metal element with respect to 100 mol of the silica particles;
0.5 mol to 25 mol of the Al in terms of metal element with respect to 100 mol of the silica particles; and
0.1 mol to 2.0 mol of the alkaline earth metal in terms of metal element with respect to 100 mol of the silica particles.

2. The phosphor according to claim 1, wherein the phosphor contains:
1.5 mol to 4.0 mol of the Eu in terms of metal element with respect to 100 mol of the silica particles; and
10 mol to 20 mol of the Al in terms of metal element with respect to 100 mol of the silica particles.

3. The phosphor according to claim 1, wherein the silica particles have an average particle size of from 5 μm to 50 μm inclusive.

4. A solar cell module comprising:
a backsheet;
a protective glass;
a first filler layer disposed between the backsheet and the protective glass;
a second filler layer disposed between the protective glass and the first filler layer;
an electrode disposed between the first filler layer and the second filler layer; and
a photoelectric conversion device disposed between the first filler layer and the second filler layer and connected to the electrode, wherein
the second filler layer contains an ultraviolet absorber-containing resin and the phosphor according to claim 1.
